(19) United States
(12) Patent Application Publication
(10) Pub. No.: US 2020/0393511 A1
(43) Pub. Date: Dec. 17, 2020

(54) WEDGED CONTACT FINGERS FOR INTEGRATED CIRCUIT TESTING APPARATUS

(71) Applicant: JF MICROTECHNOLOGY SDN. BHD., Petaling Jaya (MY)

(72) Inventors: Wei Kuong FOONG, Petaling Jaya (MY); Kok Sing GOH, Petaling Jaya (MY); Shamal MUNDIYATH, Petaling Jaya (MY); Eng Kiat LEE, Petaling Jaya (MY); Muhamad Izzat bin ROSLEE, Petaling Jaya (MY); Mei Chen CHIN, Petaling Jaya (MY)

(73) Assignee: JF MICROTECHNOLOGY SDN. BHD., Petaling Jaya (MY)

(21) Appl. No.: 16/899,480

(22) Filed: Jun. 11, 2020

(30) Foreign Application Priority Data
Jun. 12, 2019 (MY) PI 2019003329

(51) Int. Cl. G01R 31/319; G01R 1/067; G01R 1/04

(52) U.S. Cl. CPC G01R 31/31905; G01R 1/0416; G01R 1/06727

(57) ABSTRACT

An IC testing apparatus whereby a wedge body with inclined surfaces is attached to a bottom side of existing contact finger modules. The inclined support is then attached to the top of a load board of the testing apparatus. The inclined surfaces cause the normally horizontal finger modules to become inclined to the horizontal. In this manner, testing can be carried out in the usual way with existing contact finger modules, whilst the problems of IC device contact pad burr and oxidization are solved. Furthermore, because the outer, load board end of the contact fingers are also at an angle, these outer tips of the contact fingers naturally come into contact with the load board, without requiring any soldering.

### FIELD OF INVENTION

The present invention relates generally to electrical contacts, and more specifically to electrical contact fingers laid on a wedge so that it assumes an inclined posture relative to the horizontal.

### BACKGROUND OF INVENTION

Integrated Circuit (IC) testing apparatus utilizing contact fingers have long been known in the art. Contact finger modules are cheap and easy to manufacture, as well as being stronger and more robust than contact pins. All this makes them popular for use in IC testing. Due to manufacturing convenience, the most common configuration is when the contact fingers are placed in groups and arranged in a flat, horizontal plane. Each group of contact fingers is arranged in one general direction and are attached to some kind of rigid holder, which holds them together. The group of contact fingers attached to the holder is called a contact finger module. Typically, there are either two of these contact finger modules arranged so they are opposed to each other, or four of these contact finger modules arranged in a square formation as seen from a top view. Each individual contact finger may be curved across the horizontal plane, but does not deviate from that horizontal plane.

One problem with this solution relates to the contact fingers contacting the burr of the IC device contact pads. The IC device contact pads are manufactured in such a way that a burr is sometimes formed on the edge of the pads. This burr is a sharp vertical protrusion on the edge of the otherwise horizontal pads. With this burr, when the horizontal contact fingers approach the horizontal pads during testing, the contact fingers contact the burr instead of the horizontal portion of the contact pad, and hence the contact point is only a fraction of what is desired. This reduced contact causes many problems for the test. This also shortens the life of the contact fingers, as the sharp burr cuts away at and damages the contact finger.

Another problem with this solution is the lack of wiping action between the contact fingers and the IC device contact pads. Horizontal device contact pads vertically approaching the horizontal contact fingers does not produce horizontal wiping motion between the contacts. IC device contact pads can sometimes attain a build-up of oxidization on its surface, which can lead to less than optimal contact with the test contact fingers. It is preferable for the test contact fingers to have a horizontal wiping action against the IC device contact pads during testing to ensure that any oxidization is removed, and good conduction is achieved during testing.

To overcome the above problems, some solutions have included contact fingers with tips that are bent upwards. These upward-pointed contact finger tips do produce some horizontal wiping action on the IC device contact pads. However, they are difficult and costly to produce for micro IC testing apparatus. Smaller IC device contact pads require smaller contact fingers. To further complicate matters, these contact fingers usually are already curved across one plane to allow for a group of them to converge towards the extremely small area of an IC device. Making them further bent outwards of that plane requires more technical prowess during manufacture, and therefore more costs. IC devices with contact pads smaller than 2 mm or so require contact fingers too small to make with the bent upwards tips. At these sizes, it is much more economical to stick to the flat contact fingers that are level across a single plane.

In all the above solutions, because the horizontal contact fingers sit higher than the load board, they need to be soldered onto the said load board. Soldering is a time and energy consuming process, and is not desired in high volume production.

Yet a further problem with the above solutions is that for very small IC devices, even the upward-pointed contact finger tips are sometimes not able to securely contact the shorter device contact pads.

What is needed in the art is a testing apparatus that is able to utilize the less costly existing flat contact fingers that are level across a single plane, whilst also enjoying the advantages of horizontal wiping between the contact fingers and the device contact pads.

What is also needed in the art is a testing apparatus that is able to utilize the less costly existing flat contact fingers that are level across a single plane, whilst also avoiding contact with the burr on the IC device contact pads.

What is also needed in the art is a testing apparatus that is able to utilize the less costly existing flat contact fingers without requiring any soldering of the contact fingers to the load board.

What is also needed in the art is a testing apparatus that is able to utilize the less costly existing flat contact fingers to securely contact very short IC device contact pads.

### SUMMARY OF INVENTION

The present invention seeks to overcome the aforementioned disadvantages by providing an IC testing apparatus whereby a wedge body (also called an inclined support) having inclined surfaces is attached to a bottom side of existing contact finger modules. The inclined support is then attached to the top of a load board of the testing apparatus. The inclined surfaces cause the normally horizontal finger modules to become inclined to the horizontal, which effectively makes inner end tips of each contact finger at an inclined angle to the horizontal IC device contact pads. Because of this, a horizontal wiping action of the contact finger inner end tip against the IC device contact pad is generated even though there is only vertical movement of the IC device relative to the test assembly. The incline of the contact finger inner end tips also allows it to avoid edge burrs that may be present on the IC device contact pads.

Furthermore, also because the contact fingers inner end tips are inclined, the contact between it and the device contact pad is along one edge and therefore shorter than if the contact fingers were bent upwards. This allows secure contact with even very short contact pads.

In this manner, testing can be carried out in the usual way with existing contact finger modules, whilst the problems of device contact pad burr, oxidization and failed contact due to small contact sizes are reduced.

Furthermore, because the outer, load board end of the contact fingers are also at an angle, these outer end tips of the contact fingers naturally come into contact with the load board, and the usual soldering is not required. This further lowers the assembly cost and time of an IC device test done in this manner.

Typically, there are either two inclined surfaces arranged so they are opposed to each other, or four of these inclined surfaces arranged in a square formation as seen from a top down view.

This invention thus relates to an integrated circuit testing apparatus, comprising: an electrically insulative inclined support (wedge body) having at least one inclined surface, and a plurality of electrically conductive, independently flexible contact fingers placed on a plane that is parallel to the said inclined surface. The contact fingers are spaced apart from each other and substantially level with the plane of the said inclined surface.

This invention also relates to an electrically insulative holder rigidly joined to the plurality of contact fingers at an intermediate length of the plurality of contact fingers, such that an inner end of each said contact finger projects in a cantilevered fashion beyond said holder. Each plurality of contact fingers joined in this way by one holder forms a contact finger module.

In a preferred embodiment, the inclined support has two inclined surfaces located on opposing sides of the inclined support, and such that the inclined surfaces mirror each other across a vertical plane.

In another preferred embodiment, the inclined support has four inclined surfaces arranged in a square formation as seen from a top down view.

In yet another preferred embodiment, each said inclined surface is between 5° and 50° from a horizontal plane, and even more preferably between 10° and 20° from a horizontal plane. At between 10° and 20° from a horizontal plane, the horizontal wiping effect between the contact fingers and the device contact pads is at an optimum.

In yet another preferred embodiment, the inclined support is positioned, and the inclined surfaces are angled, such that outer end tips of the contact fingers come into electrical contact with load board contact pads of the testing apparatus. The outer ends of the contact fingers are at the lower end of the inclined contact finger modules, and end equidistantly from the holder. For existing contact finger modules, it is a matter of matching the size of the contact finger modules to the right combination of inclined support position and size, as well as the angle of the inclined surfaces, to achieve good contact between the contact fingers and load board contact pads, without the need for soldering of the contact fingers to the load board contact pads.

Advantages of not soldering the contact fingers to the load board contact pads include:
i) Easy changing and rebuilding of damaged contact finger modules.
ii) Flexibility to transfer the contact finger modules to different sites.
iii) Very low setup time, as the contact finger modules just have to be placed and fastened onto the inclined support.

Other objects and advantages will be more fully apparent from the following disclosure and appended claims.

### BRIEF DESCRIPTION OF DRAWINGS

FIGS. 1a, 1b, 1c and 1d show views of an existing contact finger module.

FIGS. 2a, 2b, 2c and 2d show views of an existing design well known in the art.

FIG. 3 shows a cross-sectional view of an inclined support and attached contact finger modules in an embodiment of the present invention.

FIG. 4 shows the preferred angle for each inclined surface in an embodiment of the present invention.

FIGS. 5a and 5b respectively show cross-sectional views of contact fingers in uncompressed and compressed states in an embodiment of the present invention.

FIG. 6 shows a cross-sectional view of an inclined contact finger avoiding a contact pad burr in an embodiment of the present invention.

FIG. 7 shows a bottom perspective view of inclined contact fingers coming into contact with device contact pads in an embodiment of the present invention.

FIGS. 8a and 8b show views of an inclined support with four sides in an embodiment of the present invention.

FIGS. 9a, 9b, and 9c show views of an inclined support with four sides along with attached contact finger modules in an embodiment of the present invention.

FIGS. 10a and 10b show views of an inclined support with two sides in an embodiment of the present invention.

FIGS. 11a and 11b show views of an inclined support with two sides along with attached contact finger modules in an embodiment of the present invention.

FIGS. 12a and 12b show plan views of contact fingers in an embodiment of the present invention.

### DETAILED DESCRIPTION OF INVENTION

It should be noted that the following detailed description is directed to an integrated circuit testing apparatus, and is not limited to any particular size or configuration but in fact a multitude of sizes and configurations within the general scope of the following description.

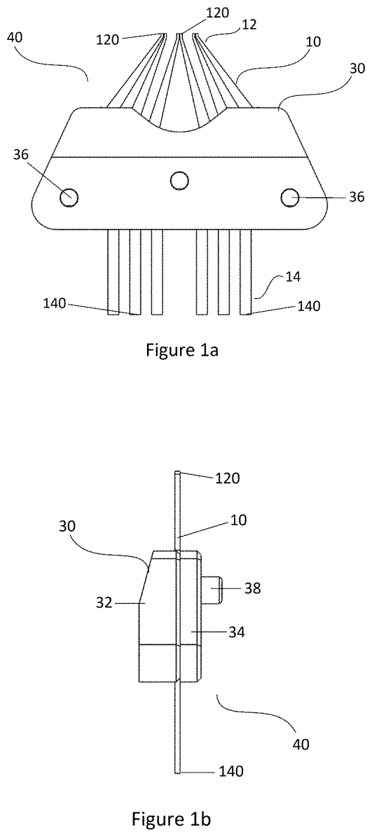

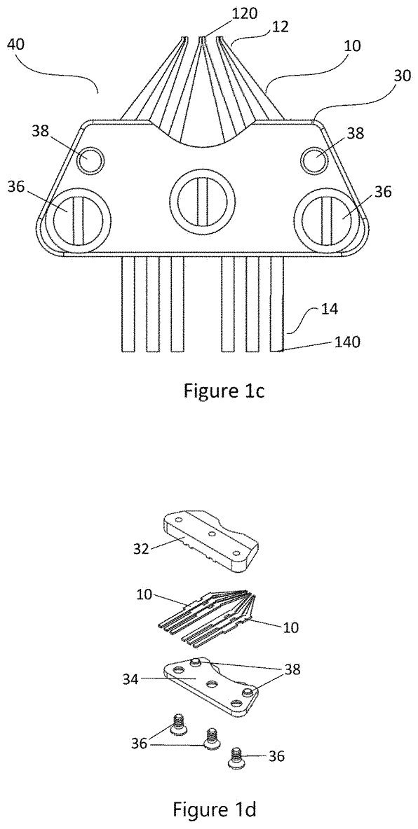

FIGS. 1a through 1d show various views of an existing contact finger module (40) that is known and is common in the prior art. FIG. 1a shows a top view of the contact finger module (40). FIG. 1b shows a side view of the contact finger module (40). FIG. 1c shows a bottom view of the contact finger module (40). FIG. 1d shows an exploded view of the contact finger module (40). A plurality of electrically conductive, independently flexible contact fingers (10) is arranged in the same general direction to each other and fastened together with a holder (30). The holder (30) comprises of an upper holder (32) and a lower holder (34) that clamp together to sandwich the plurality of contact fingers (10) using fasteners (36). It is conceivable that other methods of clamping are possible. No matter the method of clamping, the essential thing is that the holder (30) forms a substantially rigid member that secures an intermediate portion of the flexible contact fingers (10). The plurality of contact fingers (10) and holder (30) now form a contact finger module (40). A pair of contact finger module dowel pins (38) protrude from a bottom side of the holder (30).

Each contact finger (10) may be curved or bent, as can be seen in FIGS. 1a and 1c. However, they are only curved or bent across one single plane, as is apparent in FIG. 1b. The reason for this is it is more difficult technically and also costlier to manufacture contact fingers that are curved in more than one plane. This difficulty and cost are exacerbated for very small IC devices.

Each contact finger (10) has an inner end (12) located towards an IC device or device under test (DUT), which end at inner end tips (120). It is these said inner end tips (120) which come into contact with contact pads on the IC device. Each contact finger (10) has an outer end (14) located towards a load board (50) of the test assembly. These outer ends (14) end in outer end tips (140). It is these outer end tips (140) which come into contact with contact pads (52) on the load board (50).

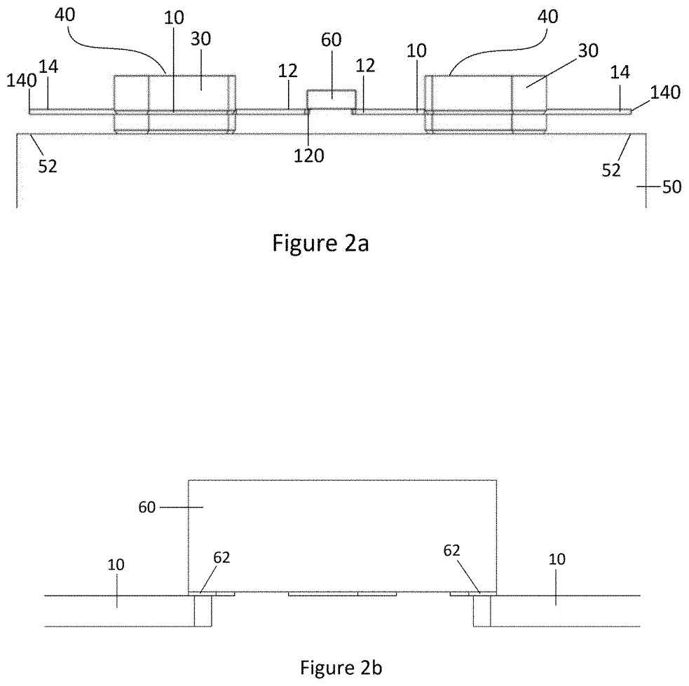

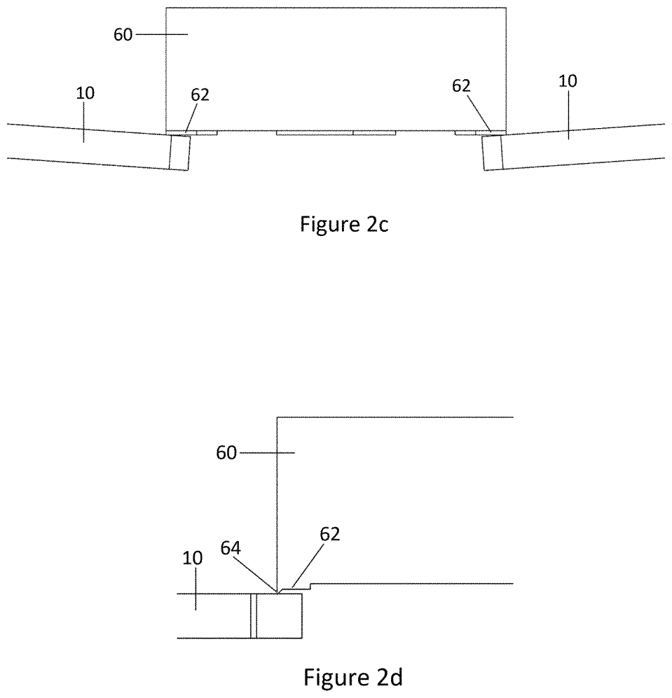

Referring to FIGS. 2a through 2d, there are shown views of an existing design common in many prior art. The contact finger modules (40) are each composed of a plurality of contact fingers (10) held together by a holder (30). Although each contact finger (10) may be curved across the horizontal plane, they are not curved or bent away from that horizontal plane, as can be seen in the cross-sectional view of FIG. 2a. This is because it is easier and less costly to produce contact finger modules (40) that have contact fingers (10) that are flat and level across a single plane. Some prior art have contact fingers (10) that are bent upwards, out of the horizontal plane, at one end, but this is technically difficult and costly, especially for very small contact finger modules (40).

Specifically referring to FIG. 2a, there is shows a cross-sectional view of an existing design common in many prior art. The contact finger modules (40) are each composed of a plurality of contact fingers (10) held together by a holder (30). An inner end (12) of each contact finger (10) ends in a tip (120) that comes into contact with a contact pad of the IC device (60) being tested. An outer end (14) of each contact finger (10), ends in a tip (140) that is a vertical distance above a contact pad (52) of a load board (50), due to the contact finger (10) being in a horizontal posture. Soldering is required to bridge this vertical gap between the tip (140) and the contact pad (52). This soldering increases the time and energy required during assembly of the contact finger modules (40).

In FIGS. 2b and 2c, the problems with this configuration can be clearly seen. As the IC device (60) is lowered onto the contact fingers and testing apparatus, the horizontal surface of the contact fingers (10) against the horizontal surface of the IC device contact pads (62) have the best contact in only a very small margin of vertical movement of the IC device (60). FIG. 2c shows that when this vertical movement is exceeded, only a small portion of the surfaces is in contact with each other. This results in a poor electrical contact between the IC device contact pads (62) and the contact fingers (10).

In FIG. 2d, the burr (64) present on the edge of the device contact pads (62) hampers proper contact between the contact fingers (10) and the device contact pads (62). The vertical burr (64) has a sharp point that reduces the contact surface between the contact fingers (10) and the IC device (60). Not only does this increase the chances of failed tests, the sharp burr (64) can, over time, cut into the side of the contact finger (10), thus damaging it and decreasing its operational lifespan.

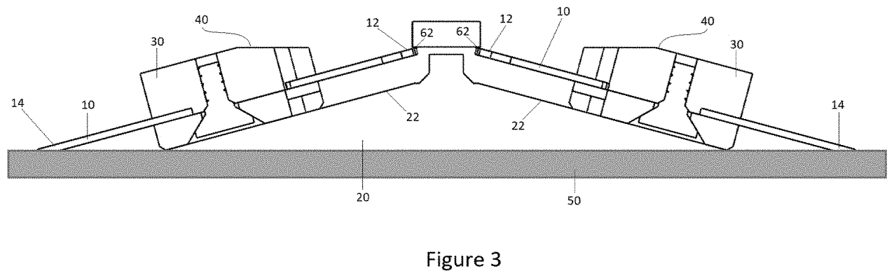

FIG. 3 shows a cross-sectional view of the present invention. An inclined support (20) having inclined surfaces (22) is attached to a bottom side of a plurality of contact finger modules (40) using contact finger module dowel pins (shown in FIG. 1b). The contact finger modules (40) are clamped in between the inclined support (20) and a housing body (not shown in this figure), and the entire assembly is then attached onto a load board of a test apparatus. The contact fingers (10) are thus on a plane that is substantially parallel to the inclined surface (22). Due to this incline, inner ends (12) of the contact fingers (10) are at an angle to the device contact pads (62).

It can also be seen in FIG. 3 that the holder (30) of the contact finger module (40) is positioned on the inclined support (20) such that outer ends (14) of the contact fingers (10) just touch and form an electrical contact with contact pads (52) on the load board (50). Unlike with the prior art, this does not require soldering of the contact fingers (10) to the load board contact pads (52). To get the outer ends (14) of the contact fingers (10) to contact the load board contact pads (52) in this way, a combination of the size and position of the inclined support (20), as well as the angle of the inclined surfaces (22), have to match the contact finger module (40) that is being used.

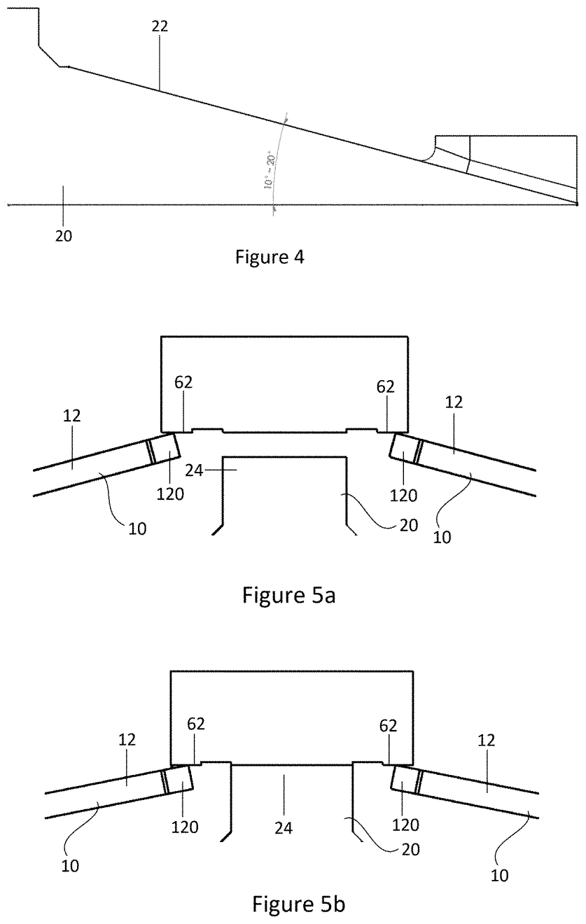

Referring to FIG. 4, there is shown the preferred angle of incline of the inclined surfaces (22) in relation to horizontal. In this preferred embodiment, the angle is between 10° and 20° to the horizontal. It has been calculated that this range of angle produces the optimum horizontal wiping stroke between the contact fingers and the device contact pads for various common sizes of contact finger modules. However, it may in some cases be necessary to go out of this range, to as much as between 5° and 50° to the horizontal.

FIGS. 5a and 5b show cross-sectional views of the contact fingers (10) engaging the device contact pads (62) in uncompressed and compressed states, respectively. In FIG. 5a, the contact finger inner end tips (120) have just come into contact with the device contact pads (62) and are uncompressed. As the device under test is lowered further, the contact finger inner end (12) flex downwards into a compressed state as shown in FIG. 5b, and in the process cause a horizontal wiping action on the device contact pads (62). This horizontal wiping action removes any oxidization that may have developed on the device contact pad (62). The lowering of the device under test (60) is halted when it hits a hardstop (24) located on the inclined support (20).

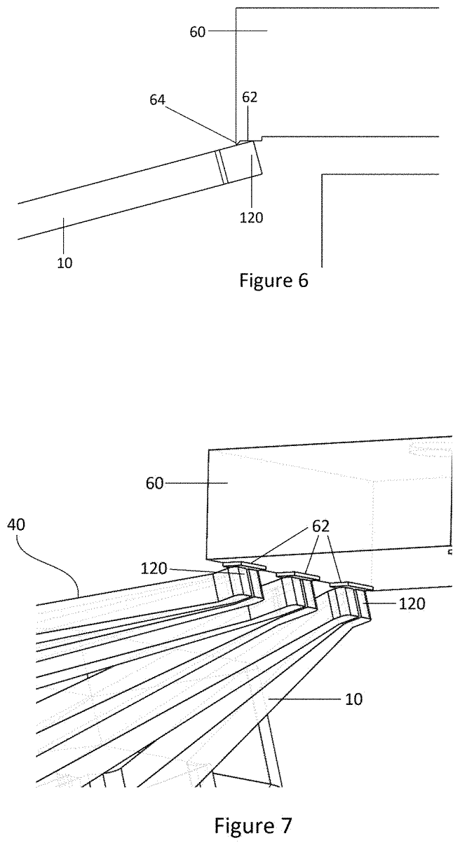

Referring to FIG. 6, there is shown a cross-sectional view of an inclined contact finger (10) of the present invention avoiding a burr (64) located on the edge of a device contact pad (62) of an IC device (60). In contrast to FIG. 1d, a much better contact is achieved here. Furthermore, the sharp burr (64) is not able to damage the contact finger (10).

It can also be seen from FIG. 6 that the contact finger inner end tip (120) comes into contact with the device contact pad (62) at an edge of the said tip (120). This allows the contact finger (10) to accurately contact even very short contact pads (62).

FIG. 7 shows a portion of the contact finger module (40) with the inner end tip (120) coming into contact with the contact pad (62) of the IC device (60). In this view, it can be clearly seen that the contact finger inner end tips (120) are able to accurately land on the device contact pads (62) due to its inclined posture. It can also be seen that that inner ends of the individual contact fingers (10) are curved and bent across a single plane, but do not deviate away from that plane.

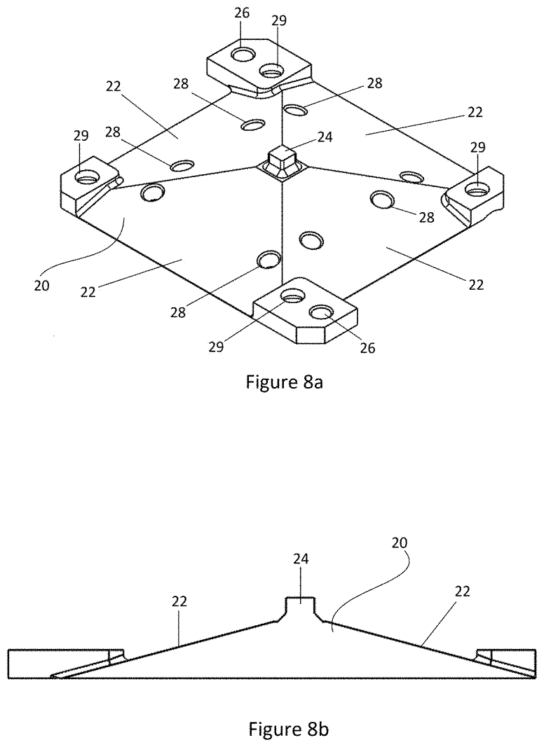

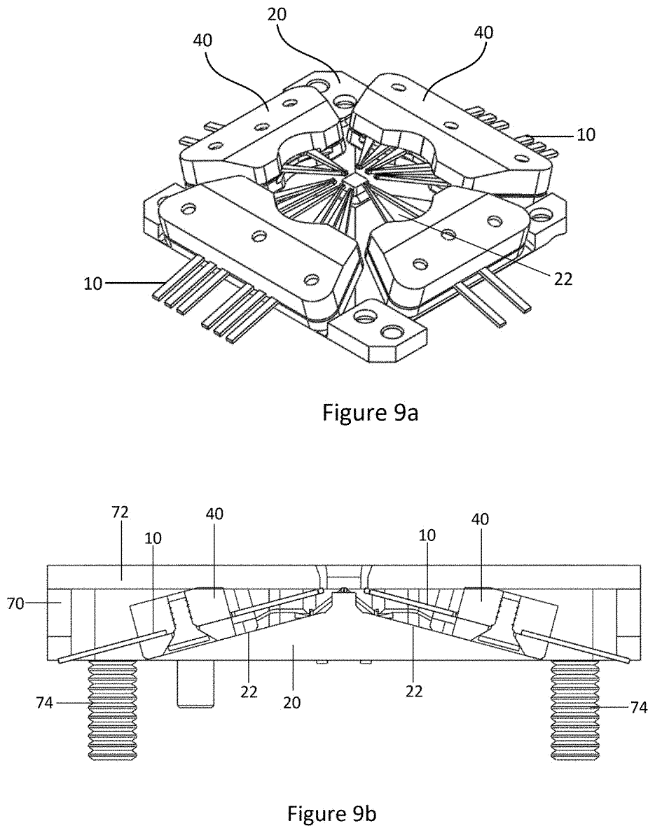

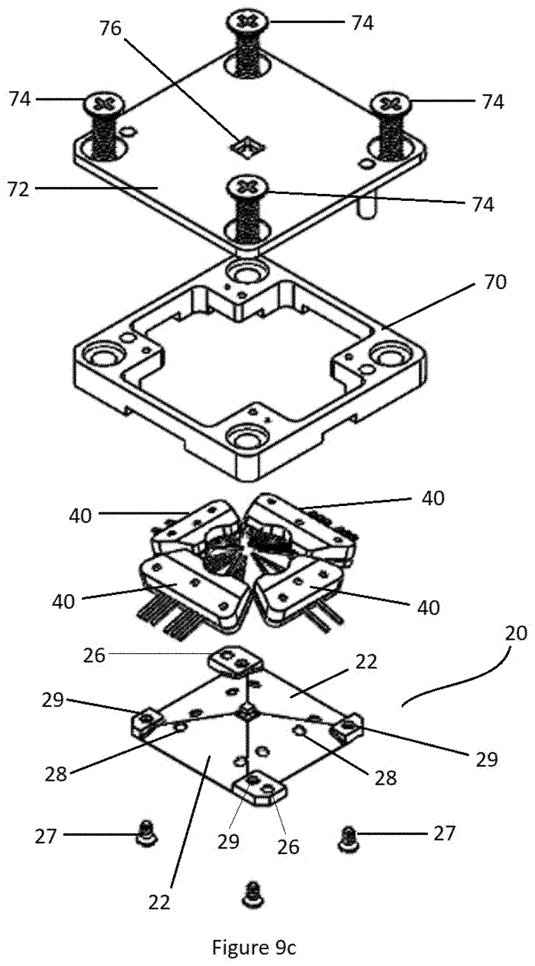

FIGS. 8a and 8b show perspective and cross-sectional views, respectively, of an inclined support (20) with four inclined surfaces (22) in an embodiment of the present invention. The four inclined surfaces (22) are arranged in a square formation as seen from a top down view. Each of the four sides of the inclined support (20) comprises a wedge shape formed by a horizontal bottom and an inclined surface (22) at an angle to the horizontal. At each corner of the inclined support (20), there are provided housing screw holes (29), which holes being threaded and adapted to receive housing screws (shown in FIG. 9c as 27) that attach this incline support (20) to a housing (shown in FIGS. 9b and 9c as 70). The contact finger modules (shown in FIG. 1a as 40) are sandwiched in between the inclined support (20) and the housing, and are secured in position in this way.

The inclined support (20) is also provided with contact finger module dowel pin holes (28) which are adapted to receive contact finger module dowel pins (shown in FIG. 1b as 38). There is also provided a hardstop (24) near the center of each inclined support (20) that stops a descending IC device being tested from descending further. There is also provided housing dowel pin holes (26) for receiving housing dowel pins located on the housing.

FIGS. 9a through 9c show views of the inclined support (20) described in FIGS. 8a and 8b along with the contact finger modules (40) described in FIGS. 1a through 1d. FIG. 9a shows a perspective view of an inclined support with four inclined surfaces (22) with a contact finger module (40) attached to each of said inclined surfaces (22). The contact fingers (10) all converge towards their inner ends, at an upper end of their incline. This convergence is necessary so that the inner end tips of the contact fingers are aligned with the usually very small IC devices.

FIGS. 9b and 9c show a cross-sectional view and an exploded view, respectively, of a fully assembled test module. This comprises the said inclined support (20) at the bottom, with a contact finger module (40) secured to each of the four inclined surfaces (22). A housing cover (72) is attached over the top of the contact finger modules (40) to prevent any debris or other contaminants from falling onto the contact finger modules (40). The cover (72) is provided with an aperture (76) at its center to allow an IC device under test to go through for contact with the contact fingers (10).

Still referring to FIGS. 9b and 9c, the inclined support (20) is attached to the housing (70) by a set of housing screws (27) that pierce through housing screw holes (29) provided on the inclined support (20). These housing screws (27) extend upwards through the said housing screw holes (29) and into the body of the housing (70), thus securing the inclined support (20) to the housing (70). As the contact finger modules (40) are sandwiched between the inclined support (20) and the housing (70), they too are secured in this way. A set of load board screws (74) near each corner of the cover (72) extend downwards through holes provided in the cover (72) and the housing (70). These load board screws (74) are used to attach the test module onto the load board.

While FIGS. 8a, 8b, 9a, 9b and 9c describe the embodiment of this invention where the inclined support (20) has four inclined surfaces (22), the general way in which the test module is put together can also be applied to the embodiment where the inclined support (20) has two inclined surfaces (22).

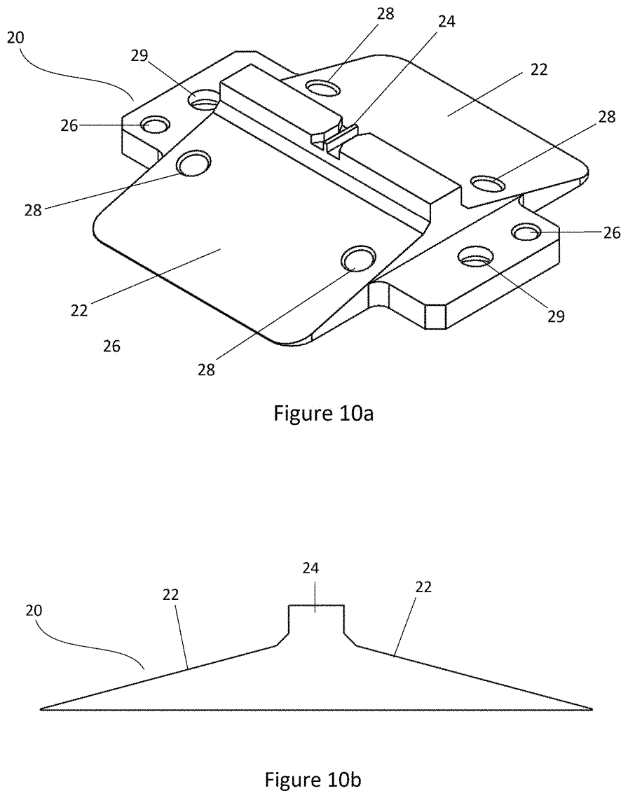

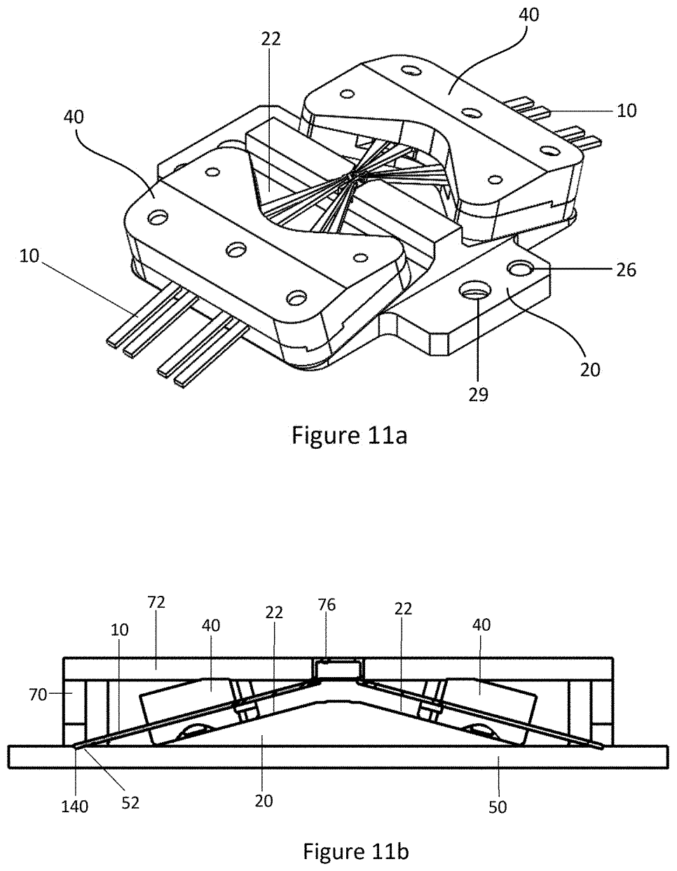

FIGS. 10a and 10b show perspective and cross-sectional views, respectively, of an inclined support (20) with two inclined surfaces (22) in an embodiment of the present invention. The two inclined surfaces (22) are arranged opposing each other, and mirror each other across a vertical plane. Each of the two sides of the inclined support (20) comprises a wedge shape formed by a horizontal bottom and an inclined surface (22) at an angle to the horizontal. At two sides of the inclined support (20) next to where the two inclined surfaces (22) meet, there are provided housing dowel pin holes (26), which holes being threaded and adapted to receive housing screws that attach this incline support (20) to a housing (shown in FIG. 11b as 70). The contact finger modules (shown in FIG. 1a as 40) are sandwiched in between the inclined support (20) and the housing, and are secured in position in this way.

The inclined support (20) is also provided with contact finger module dowel pin holes (28) which are adapted to receive contact finger module dowel pins (shown in FIG. 1b as 38). There is also provided a hardstop (24) near the center of each inclined support (20) that stops a descending IC device being tested from descending further. There is also provided housing dowel pin holes (26) for receiving housing dowel pins located on the housing.

FIGS. 11a and 11b show views of the inclined support (20) described in FIGS. 10a and 10b along with the contact finger modules (40) described in FIGS. 1a through 1d. FIG. 11a shows a perspective view of an inclined support with two inclined surfaces (22) with a contact finger module (40) attached to each of said inclined surfaces (22). The contact fingers (10) all converge towards their inner ends, at an upper end of their incline. This convergence is necessary so that the inner end tips of the contact fingers are aligned with the usually very small IC devices.

FIG. 11b shows a cross-sectional view of a fully assembled test module along with a load board (50). The test module comprises the said inclined support (20) at the bottom, with a contact finger module (40) secured to each of the two inclined surfaces (22). A housing cover (72) is attached over the top of the contact finger modules (40) to prevent any debris or other contaminants from falling onto the contact finger modules (40). The cover (72) is provided with an aperture (76) at its center to allow an IC device under test to go through for contact with the contact fingers (10).

Referring to both FIGS. 11a and 11b, the inclined support (20) is attached to the housing (70) by a set of housing screws that pierce through housing screw holes (29) provided on the inclined support (20). These housing screws extend upwards through the said housing screw holes (29) and into the body of the housing (70), thus securing the inclined support (20) to the housing (70). As the contact finger modules (40) are sandwiched between the inclined support (20) and the housing (70), they too are secured in this way. A set of load board screws near each corner of the cover (72) extend downwards through holes provided in the cover (72) and the housing (70). These load board screws are used to attach the test module onto the load board (50).

FIG. 11b also clearly shows how the outer end tips (140) of the contact fingers (10) just reaches contact pads (52) on the load board (50). A combination of the size and position of the inclined support (20), as well as the angle of the inclined surfaces (22) relative to the horizontal, produces this effect of the outer end tips (140) just contacting the contact pads (52). As this invention intends to utilize for the most part existing contact finger modules (40), and these contact finger modules (40) come in various sizes and lengths of contact fingers, the variables mentioned above: size and position of the inclined support (20), and angle of the inclined surface (22) can be precisely calculated and then manufactured in order to achieve this contact between the outer end tips (140) and the contact pads (52) of the load board (50). This avoids the need to solder the contact fingers onto the load board contact pads (52).

While FIGS. 10a, 10b, 11a and 11b describe the embodiment of this invention where the inclined support (20) has two inclined surfaces (22), the general way in which the test module is put together can also be applied to the embodiment where the inclined support (20) has four inclined surfaces (22).

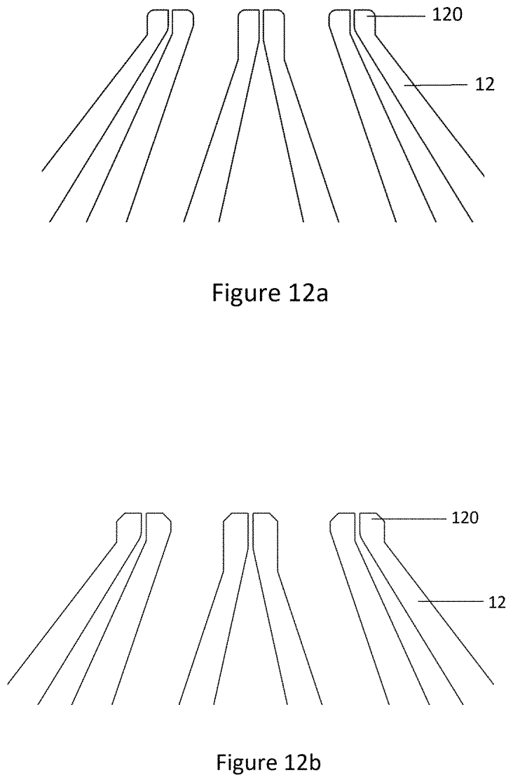

FIG. 12a shows a plan view of contact finger inner ends (12) with tips (120) that are rounded, in one embodiment of this invention. This makes the inner end tips (120) even smaller, to accommodate even smaller IC device contact pads. Rounded end tips (120) as shown in FIG. 12a result in a gentler horizontal scrubbing action between the end tips (120) and the IC device contact pads, during testing.

FIG. 12b shows a plan view of contact finger inner ends (12) with tips (120) that are chamfered, in another embodiment of this invention. This makes the inner end tips (120) even smaller, to accommodate even smaller IC device contact pads. Chamfered end tips (120) as shown in FIG. 12b result in a horizontal scrubbing action between the end tips (120) and the IC device contact pads that is harsher than that of rounded end tips, during testing.

In both FIGS. 12a and 12b, smaller end tips reduce the likelihood of the end tips touching an IC chip mold substrate in the event there is any slight misalignment during the test.

While several particularly preferred embodiments of the present invention have been described and illustrated, it should now be apparent to those skilled in the art that various changes and modifications can be made without departing from the scope of the invention. Accordingly, the following claims are intended to embrace such changes, modifications, and areas of application that are within the scope of this invention.

### LIST OF NUMBERED ELEMENTS IN FIGURES

Contact finger (10)
Contact finger inner end (12)
Contact finger inner end tip (120)
Contact finger outer end (14)
Contact finger outer end tip (140)
Inclined support/Wedge body (20)
Inclined surface (22)
Inclined support hardstop (24)
Housing dowel pin holes (26)
Housing screws (27)
Contact finger module dowel pin holes (28)
Housing screw holes (29)
Holder (30)
Upper holder (32)
Lower holder (34)
Holder fastener (36)
Contact finger module dowel pin (38)
Contact finger module (40)
Load board (50)
Load board contact pads (52)
IC device (60)
IC device contact pads (62)
Burr (64)
Housing (70)
Cover (72)
Load board screws (74)

1. An integrated circuit testing apparatus, comprising:
an electrically insulative inclined support having at least one inclined surface;
a plurality of electrically conductive, independently flexible contact fingers placed on a plane parallel to said inclined surface, said contact fingers spaced apart from each other and substantially level with said plane.

2. An integrated circuit testing apparatus according to claim 1, further comprising an electrically insulative holder rigidly joined at an intermediate length of said plurality of contact fingers such that an inner end of each said contact finger projects in a cantilevered fashion beyond said holder.

3. An integrated circuit testing apparatus according to claim 1, wherein the said inclined support has two inclined surfaces located on opposing sides of said inclined support and such that the inclined surfaces mirror each other across a vertical plane.

4. An integrated circuit testing apparatus according to claim 1, wherein the said inclined support has four inclined surfaces arranged in a square formation as seen from a top down view.

5. An integrated circuit testing apparatus according to claim 1, wherein the said inclined surface is between 5° and 50° from a horizontal plane.

6. An integrated circuit testing apparatus according to claim 1, wherein the said inclined surface (is between 10° and 20° from a horizontal plane.

7. An integrated circuit testing apparatus according to claim 1, wherein the said inclined support is positioned, and the said inclined surfaces are angled, such that outer end tips of said contact fingers come into electrical contact with load board contact pads of said testing apparatus.
